(19) United States
(12) Patent Application Publication
(10) Pub. No.: US 2011/0269251 A1
(43) Pub. Date: Nov. 3, 2011

(54) Spin Transfer Torque Memory Device Having Common Source Line and Method for Manufacturing the Same

(75) Inventors: Hyun Jeong Kim, Yongin-si (KR); Sung Woong Chung, Icheon-si (KR)

(73) Assignee: HYNIX SEMICONDUCTOR INC., Icheon-si (KR)

(21) Appl. No.: 13/178,274

(22) Filed: Jul. 7, 2011

Related U.S. Application Data
(62) Division of application No. 12/343,556, filed on Dec. 24, 2008.

(30) Foreign Application Priority Data
Sep. 9, 2008 (KR) 10-2008-0088823

(51) Int. Cl. H01L 21/8246

(52) U.S. Cl. 438/3; 257/E21.665

(57) ABSTRACT

A spin transfer torque memory device and a method for manufacturing the same. The spin transfer torque memory device comprises a MRAM cell using a MTJ and a vertical transistor. A common source line is formed in the bottom of the vertical transistor, thereby obtaining the high-integrated and simplified memory device.

This application is a division of U.S. application Ser. No. 12/343,556, filed Dec. 24, 2008, which claims priority to Korean Patent Application No. 10-2008-0088823, filed on Sep. 9, 2008, the disclosures of which are hereby expressly incorporated herein for all purposes.

### BACKGROUND OF THE INVENTION

The present invention generally relates to a spin transfer torque memory (STT-MRAM), and more specifically, to a STT-MRAM having a common source line and a method for manufacturing the same.

Out of all semiconductor memory devices, DRAM has had the largest market share.

The DRAM that includes one MOS transistor and one capacitor which are paired is a memory device operated as one bit. The DRAM requires a periodic refresh operation in order not to lose data because the DRAM stores charges in the capacitor to write data.

A nonvolatile memory which have stored signals that are not destroyed when a power source turns off such as a hard disk includes NAND/NOR flash memory. Specifically, the NAND flash memory has the highest integration among the memories. This flash memory is light because its size is smaller than a hard disk, and is also resilient to a physical impact. Also, the flash memory has a rapid access speed with low power consumption, so that the flash memory has been widely used as a storage media of mobile products. However, the flash memory has a slower speed and a higher operating voltage than that of the DRAM.

The memory serves plenty of uses. As mentioned above, the DRAM and the flash memory are adopted in different products depending on their different characteristics. Recently, a memory that has advantages of these two memories has been developed for commercial usage. For example, some of these include phase change RAM (PCRAM), magnetic RAM (MRAM) and polymer RAM (PoRAM) and Resistive RAM (ReRAM).

The MRAM employs resistance change depending on polarity change of a magnetic material as a digital signal. The MRAM has been successfully used in commercialization of products with low capacity. Since the MRAM employs magnetism, the MRAM is not damaged by radioactivity in space, so that the MRAM is the most stable memory.

FIG. 1 is a cross-sectional diagram illustrating a conventional MRAM structure.

The write operation of MRAM is performed by the vector sum of the magnetic field generated by current flowing over a bit line B/L and the magnetic field generated by current flowing over a digit line D/L when the current flows simultaneously in the bit line B/L and the digit line D/L.

That is, as shown in FIG. 1, the conventional MRAM using magnetic fields is configured to include a bit line and an additional digit line. As a result, the cell size becomes larger, thereby degrading the cell efficiency in comparison to other types of memory.

In the MRAM, a half-selection state exposed to the magnetic field generated in the neighboring line occurs so that it is easy to generate a disturbance phenomenon that inverts the neighboring cell in a write mode. Furthermore, a switching operation by the magnetic field requires a larger current as the size of the Magnetic Tunnel Junction (MTJ) is smaller, thereby degrading the high integration.

Recently, a STT-MRAM has been developed. The STT-MRAM does not require a digit line, so that the size of the STT-MRAM can be smaller and prevent the disturbance phenomenon by the half-selection state.

FIG. 2 is a circuit diagram illustrating a unit cell of a STT-MRAM.

A STT-MRAM cell comprises a transistor 12 and a MTJ which are connected between a bit line BL and a source line SL.

The transistor 12 connected between the source line SL and is turned on depending on a voltage applied on a word line WL when data are read/written, so that current may flow between the source line SL and the bit line BL through the MTJ. The MTJ is connected between the bit line BL and source/drain regions of the transistor 12. The MTJ includes two magnetic layers 14 and 18, and a tunnel barrier layer 16 between the magnetic layers 14 and 18. The bottom layer of the tunnel barrier layer 16 is a pined ferromagnetic layer 14 where the magnetization direction is fixed. The top layer of the tunnel barrier layer 16 is a free ferromagnetic layer 18 where the magnetization direction is changed depending on a direction of current applied to the MTJ.

In the free ferromagnetic layer 18, the magnetization direction is switched in parallel to that of the pinned ferromagnetic layer 14 when the current flows from the source line SL to the bit line BL, that is, when the current flows from the pinned ferromagnetic layer 14 to the free ferromagnetic layer 18. As a result, the MTJ changes to a low resistance state, so that a data “0” is stored in the corresponding cell.

On the other hand, when the current flows from the bit line BL to the source line SL, that is, when the current flows from the free ferromagnetic layer 18 to the pinned ferromagnetic layer 14, the magnetization direction of the free ferromagnetic layer 18 is switched in anti-parallel to that of the pinned ferromagnetic layer 14. As a result, the MTJ changes to a high resistance state, so that a data “1” is stored in the corresponding cell.

The data stored in the MTJ is read by sensing a difference in the current amount flowing through the MTJ depending on a changed magnetization state of the MTJ.

Since a write method using this STT phenomenon requires a smaller current as the size of the MTJ becomes smaller, inventors are concerned of its usage possibility.

When a planar transistor is used in the STT-MRAM, there is a limit in the current amount flowing in the MTJ as the memory becomes highly integrated.

In order to solve the above problem, a vertical transistor that has been used in a conventional DRAM can be applied to the STT-MRAM. However, in this case, since the critical dimension of a buried bit line (BBL) used as a source line is narrow, the resistance of the source line becomes larger. When the data of the MTJ is read, its signal is degraded, and the size of current required in the write mode is limited.

### SUMMARY OF THE INVENTION

Various embodiments of the invention are directed at providing an improved spin transfer torque memory device, thereby reducing resistance of a source line for high integration.

According to an embodiment of the invention, a spin transfer torque memory device comprises: a pillar including a region surrounded by a surrounding gate electrode; a common source line for connecting lower portion of the pillar in common; and a magnetic tunnel junction (MTJ) formed over the pillar.

The spin transfer torque memory device further comprises: a word line for connecting the surrounding gate electrodes in a first direction; and a bit line for connecting the top portion of the MTJ in a second direction intersected with the first direction.

In the spin transfer torque memory device, a pinned ferromagnetic layer of the MTJ includes a anti-ferromagnetic material such as MnPt and MnIr. The region is formed to be concave. The common source line is obtained by ion-implanting impurities into a silicon substrate. The common source line includes a metal film formed over the silicon substrate. The MTJ is formed to have a square shape with a ratio of width:length=1:1˜1:5 or to have an oval shape with a ratio of major axis:minor axis=1:1˜1:5. The MTJ is a perpendicular MTJ where a magnetization direction is formed perpendicular to the surface. The MTJ is includes TbCoFe or FePt.

According to an embodiment of the invention, a method for manufacturing a spin transfer torque memory device comprises: forming a surrounding gate electrode in a circumference of a pillar; implanting impurities into a silicon substrate to form a common source line; and forming a MTJ over the pillar.

The method further comprises forming a word line for connecting the surrounding gate electrode along a first direction, and ion-implanting impurities into the top portion of the pillar to form a junction region.

According to another embodiment of the invention, a method for manufacturing a spin transfer torque memory device comprises: forming a metal film over a silicon substrate; selectively etching the metal film to expose the silicon substrate of a pillar region; growing the exposed silicon substrate to form a pillar; and forming a MTJ over the pillar.

The method further comprises: forming a surrounding gate electrode in the circumference of the pillar; and forming a word line for connecting the surrounding gate electrode along a first direction. The method may further comprise ion-implanting impurities into the top portion of the pillar to form a junction region.

### BRIEF DESCRIPTION OF THE DRAWINGS

FIG. 1 is a cross-sectional diagram illustrating a conventional MRAM structure.

FIG. 2 is a circuit diagram illustrating a unit cell of a STT-MRAM.

FIG. 3 is a diagram illustrating a spin transfer torque memory device according to an embodiment of the invention.

FIG. 4 is a circuit diagram illustrating the memory device of FIG. 3.

FIGS. 5a to 5f are cross-sectional diagrams illustrating a method for manufacturing a spin transfer torque memory device according to an embodiment of the invention.

FIGS. 6a to 6f are cross-sectional diagrams illustrating a method for manufacturing a spin transfer torque memory device according to another embodiment of the invention.

FIG. 7 is a diagram illustrating a spin transfer torque memory device according to another embodiment of the present invention.

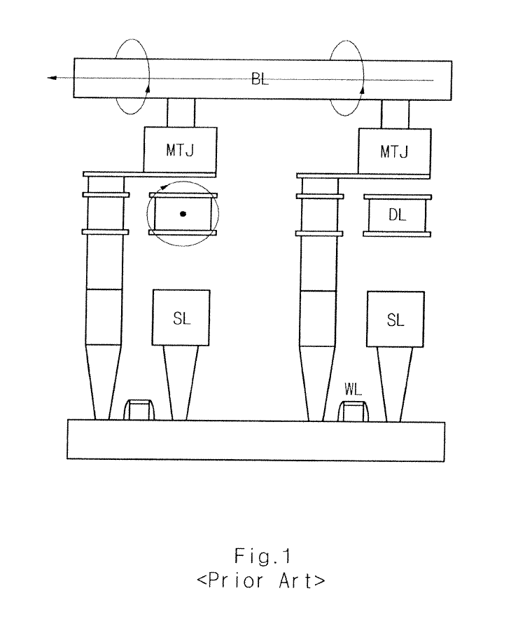

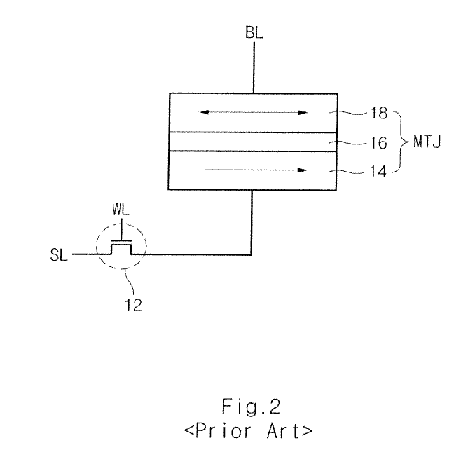

### DESCRIPTION OF SPECIFIC EMBODIMENTS

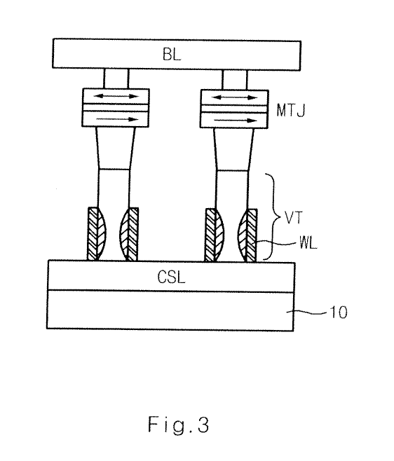

FIG. 3 is a diagram illustrating a spin transfer torque memory device according to an embodiment of the invention.

The spin transfer torque memory device of FIG. 3 comprises a common source line (CSL), a vertical transistor (VT), a Magnetic Tunnel Junction (MTJ) and a bit line (BL).

The CSL formed over a silicon substrate 10 connects source/drain regions of the bottom portion of the VT in common. In order to obtain the CSL, after a pillar for forming the VT is formed, impurities are ion-implanted into the silicon substrate. Otherwise, before the pillar is formed, a metal is deposited over the silicon substrate 10. In this way, the CSL having a large area is formed to connect the source/drain regions of the VT in common in a cell region. As a result, the resistance of the source line can be reduced, and it is not necessary to form an additional selecting circuit (not shown) for selecting the source line during a data write mode in a core region (not shown).

The VT is formed over the CSL. A surrounding gate (WL) is formed on the circumference in the bottom portion of the pillar, thereby forming a vertical channel between the CSL and the MTJ.

The MTJ connected between the VT and the BL is two magnetic layers and a tunnel barrier layer between the magnetic layers. The bottom layer of the tunnel barrier layer is a pinned ferromagnetic layer where the magnetization direction is fixed. The top layer of the tunnel barrier layer includes a free ferromagnetic layer where the magnetization layer is changed depending on a direction of current applied to the MTJ. The pinned ferroelectric layer includes an anti-ferromagnetic layer such as MnPt and Mnlr so that it is difficult to change the magnetization direction rather than in the free ferromagnetic layer. In the free ferromagnetic layer, the magnetization direction is switched (at a low resistance state) in parallel to that of the pinned ferromagnetic layer when current flows from the CSL to the BL while switched (at a high resistance state) in anti-parallel to that of the pinned ferromagnetic layer when the current flows from the BL to the CSL.

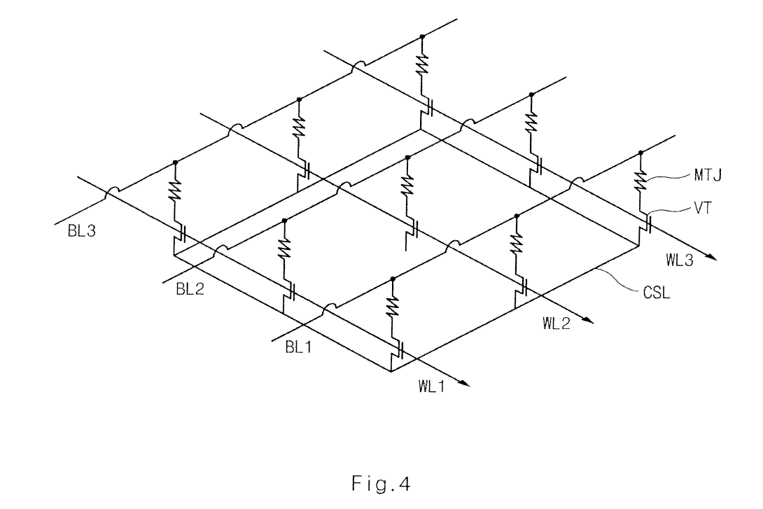

FIG. 4 is a circuit diagram illustrating the memory device of FIG. 3.

The MTJ and the VT are serially connected in a vertical direction between bit lines BL1˜BL3 and the CSL.

A gate electrode of the VT connected to word lines WL1˜WL3 controls the flow of current between the CSL and the BL through the MTJ depending on a voltage applied on the word lines WL˜WL3 during data read/write modes.

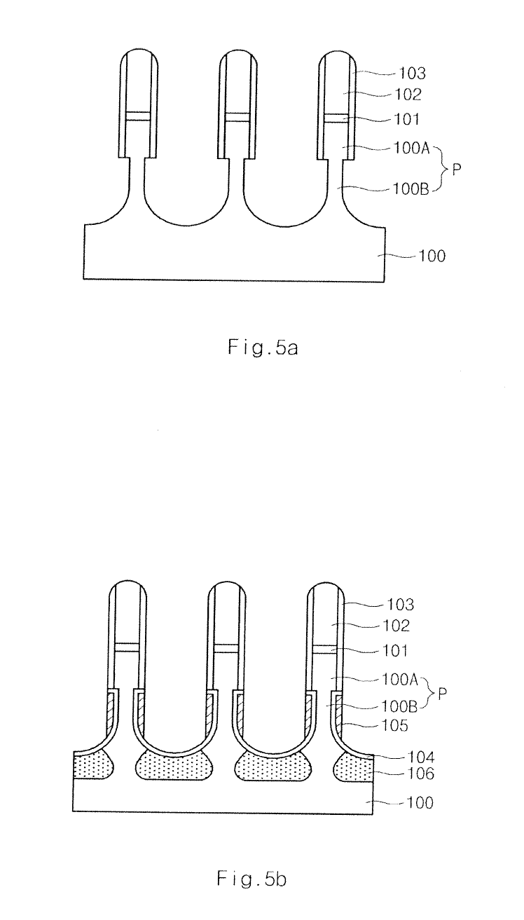

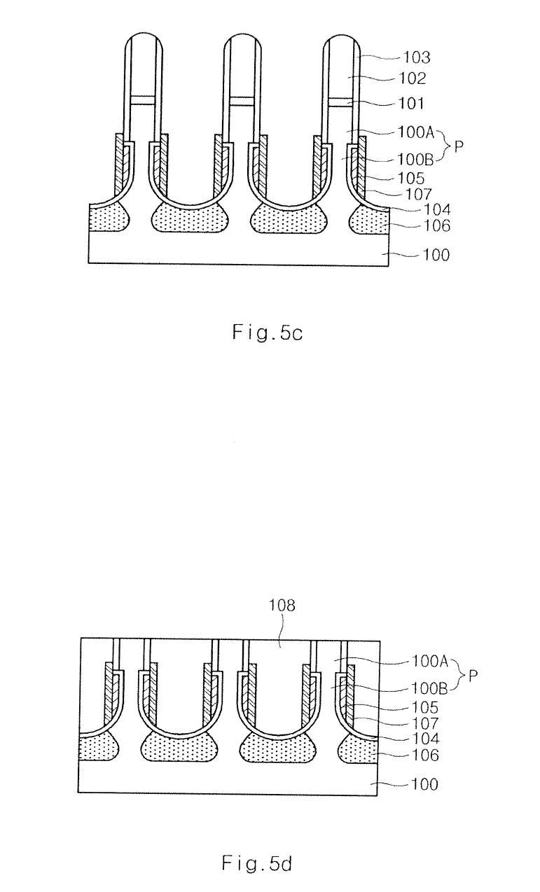

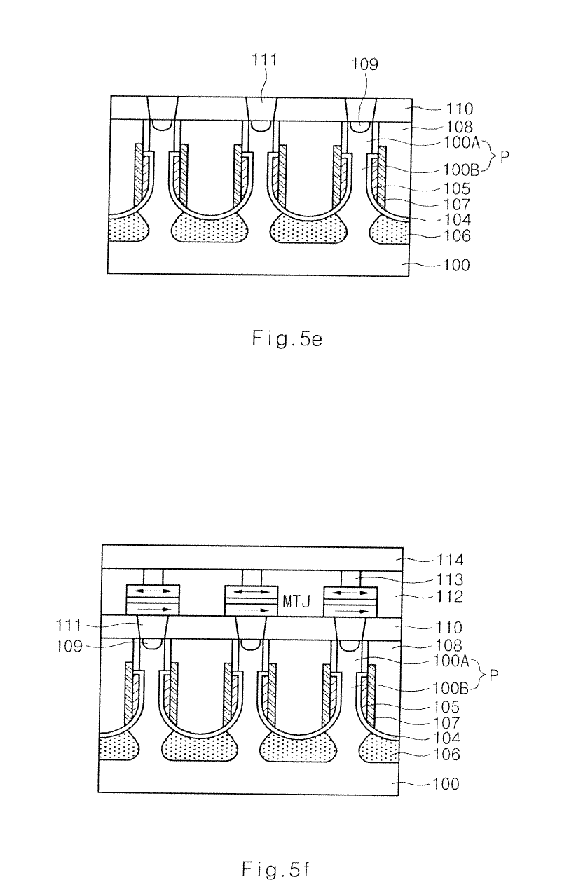

FIGS. 5a to 5f are cross-sectional diagrams illustrating a method for manufacturing a spin transfer torque memory device according to an embodiment of the invention.

Referring to FIG. 5a, a pad oxide film 101 and a hard mask pattern 102 are formed over a silicon substrate 100. The oxide film 101 and the silicon substrate 100 are etched at a given depth with the hard mask pattern 102 as an etching mask, thereby forming a top portion 100A of a pillar. The top portion 100A of the pillar may be a source region by a subsequent impurity ion-implanting process. The top surface is connected to a lower electrode contact (or a lower electrode of a MTJ).

An oxide film (not shown) and a nitride film (not shown) are sequentially formed over the resulting structure, thereby forming a spacer material film. The spacer material film is etched back to form a spacer 103 at sidewalls of the hard mask pattern 102 and the top portion 100A of the pillar.

The silicon substrate 100 is etched at a given depth with the spacer 103 as an etching mask, thereby forming a bottom portion 100B of the pillar which is connected to the top portion 100A of the pillar. The bottom portion 100B of the pillar is a channel region. As a result, pillars P including the bottom portion 100B and the top portion 100A are formed as an active region. The pillars P are separated with a given space from each other to have a matrix pattern in a cell region.

The sidewall of the bottom portion 100B of the pillar is isotropic-etched corresponding to a given width with the spacer 103 as an etching barrier. The etching degree of the bottom portion 100B of the pillar is determined in consideration of a thickness of a subsequent surrounding gate electrode.

Referring to FIG. 5b, a gate oxide film (insulating film) is formed over the silicon substrate 100 exposed by the isotropic-etching process. In order to form the CSL, impurities are ion-implanted into the silicon substrate 100 between the pillars, thereby obtaining a common source line impurity region 106. The ion-implanted impurities may be n-type impurities (Ph, As). Impurities may be ion-implanted so that the common source line impurities regions 106 may be interconnected.

After a gate electrode conductive film (e.g., a polysilicon film) is formed over the resulting structure, the gate electrode conductive film is etched back with the spacer 103 as an etching mask until the gate oxide film 104 is exposed. As shown in FIG. 5b, a surrounding gate electrode 105 that surrounds the circumference of the bottom portion 100B of the pillar is formed.

Referring to FIG. 5c, after a word line conductive film is formed over the resulting structure, the word line conductive film is removed at a given height from the top portion of the gate electrode 105. The word line conductive film is selectively etched until the gate oxide film 104 is exposed, thereby forming a damascene word line 107 that surrounds gate electrodes of the pillars P and is extended to a first direction. That is, a word line 107 connects the gate electrodes 105 of the pillars P arranged in the first direction in the cell region.

Referring to FIG. 5d, after an interlayer insulating (ILD) film 108 is formed over the resulting structure, a planarizing process is performed to remove the pad oxide film 101, the hard mask pattern 102 and the insulating film 108 until the top portion 100A of the pillar is exposed. The interlayer insulating film 108 includes an oxide film or a nitride film.

Referring to FIG. 5e, impurities are ion-implanted into the top portion 100a of the pillar in order to form a source/drain region 109. After an ILD film 110 is formed over the resulting structure, the ILD film 110 is selectively etched with a lower electrode contact hole pattern (not shown), thereby obtaining a lower electrode contact hole (not shown). After a conductive film is formed to fill the lower electrode contact hole (not shown), the conductive film is etched to expose the ILD film 110, thereby forming a lower electrode contact 111 that connects to the top portion 100A of the pillar.

Referring to FIG. 5f, a pinned ferromagnetic layer, a tunnel junction layer and a free ferromagnetic layer are sequentially formed over the ILD film 110 including the lower electrode contact 111. The pinned ferromagnetic layer, the tunnel junction layer and the free ferromagnetic layer are patterned to form a magnetic tunnel junction (MTJ) that connects to the lower electrode contact 111.

The MTJ is formed to have a square shape with a ratio of width:length=1:1˜1:5 so that the MTJ may have a desired spin direction. For example, when the MTJ has a length of 1 F in a direction of the word line 107, the MTJ has a length ranging from 1 to 5 F in a direction of the bit line 114, and vice versa. Otherwise, the MTJ is formed to have an oval shape with a ratio of major axis:minor axis=1:1˜1:5.

After an ILD film 112 is formed over the MTJ and the ILD film 111, the ILD film 112 is etched and planarized. Until the free ferromagnetic layer of the MTJ is exposed, the ILD film 112 is selectively etched to form an upper electrode contact hole (not shown). Preferably, the upper electrode contact hole is formed to expose the center of the MTJ. However, by using a patterning mask used when a lower electrode contact (not shown) is formed, an upper electrode (not shown) is formed at the same position as the lower electrode contact hole, thereby reducing a patterning mask step. After a conductive film is formed to fill the top electrode contact hole, the conductive film is etched to expose the ILD film 112, thereby obtaining an upper electrode contact 113.

The lower electrode contact 111 and the top electrode contact 113 include one selected from the group consisting of W, Ru, Ta and Cu.

After a metal film (not shown) is formed over the ILD film 112 including the top electrode contact 113, the metal film is patterned with a mask (not shown) that defines a bit line, thereby forming a bit line 114 in a second direction that intersects the word line 107.

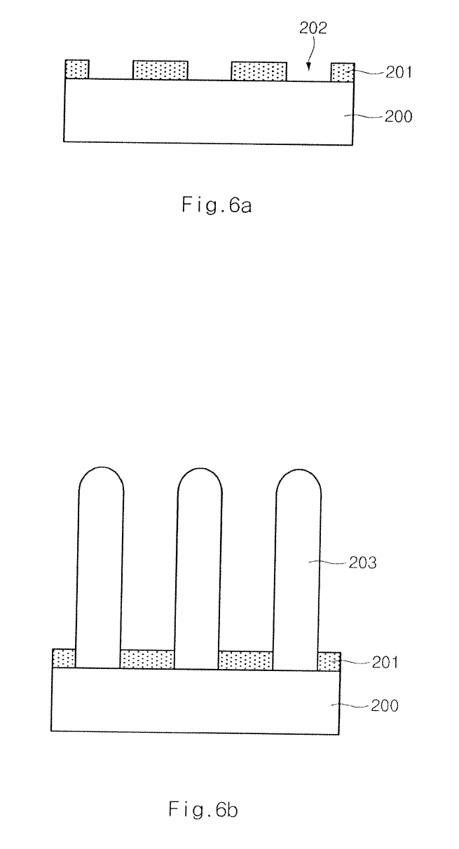

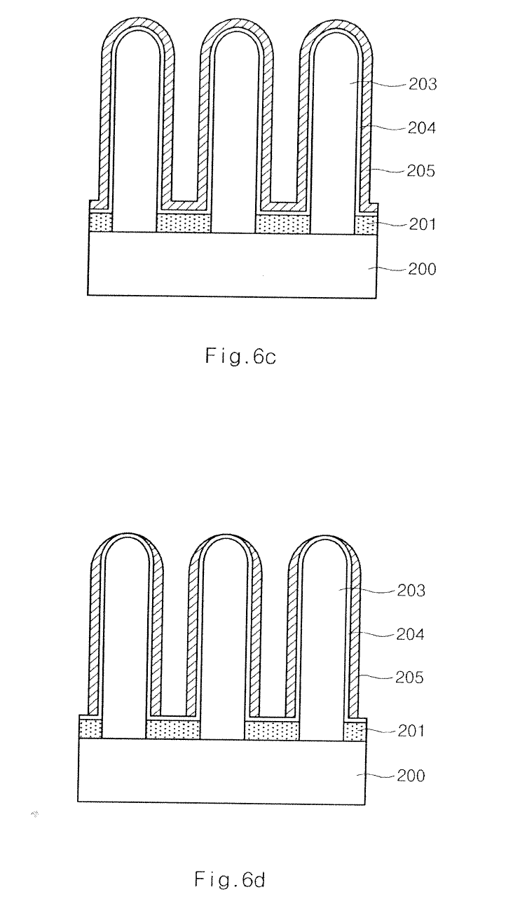

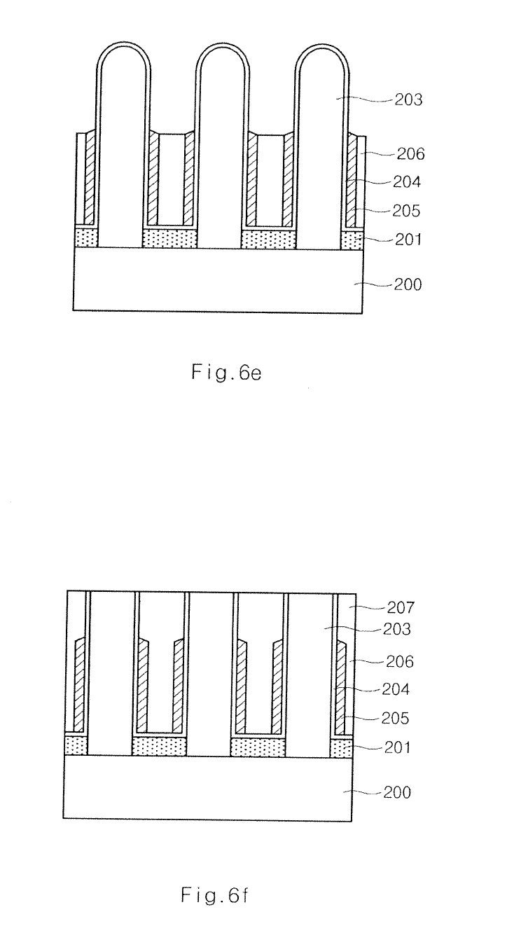

FIGS. 6a to 6f are cross-sectional diagrams illustrating a method for manufacturing a spin transfer torque memory device according to another embodiment of the invention.

Referring to FIG. 6a, after a metal film 201 used as a common source line is formed over a silicon substrate 200, the metal film 201 is selectively etched to expose the silicon substrate 200 of a region 202 where pillars are formed. A plurality of pillar regions 202 are formed to have a matrix pattern in a first direction and in a second direction that intersects the first direction.

Referring to FIG. 6b, the exposed silicon substrate 200 is grown to form a pillar 203. The growth method includes an epitaxial growth method or any silicon growth methods that have been used.

Referring to FIG. 6c, a gate oxide film 204 and a gate electrode material 205 are sequentially formed over the pillar 203 and the metal film 201. The gate electrode material 205 is formed to have a similar thickness to that of a surrounding gate electrode by a vapor chemical deposition method. The gate electrode material 205 may include a metal material selected from the group consisting of Ti, TiN, TaN, W, Al, Cu, WSix and combinations thereof or a P-type polysilicon.

Referring to FIG. 6d, the gate electrode material 205 is dry-etched to remove the gate electrode material 205 formed over the metal film 201. As a result, a device isolation process is performed on the gate electrode materials 205 deposited on each pillar 203.

Referring to FIG. 6e, after a space between the pillars 203 is filled with an insulating film (not shown), a dry etching process is performed on the resulting structure to etch an insulating film 206. The insulating film 206 is etched to a depth where a surrounding gate is formed in a subsequent process. A portion which is not filled by the insulating film 206 in the gate electrode material 205 is removed. The etching method of the gate electrode 205 includes an isotropic etching method such as a wet etching method.

As a result, a surrounding gate electrode where the bottom portion of the pillar 203 is surrounded with a given height by the gate electrode material 205 is formed.

Referring to FIG. 6f, after a nitride film (not shown) is deposited over the exposed gate oxide film 204, the insulating film 206 is removed. An insulating film 207 is formed over the resulting structure, the nitride film (not shown), the gate oxide film 204, the pillar 203 and the insulating film 207 are removed so that the top portion of the pillar may remain to a given height.

Thereafter, impurities for forming source/drain region 209 are ion-implanted into the top portion of the pillar. The processes shown in FIGS. 5a to 5f may be performed to form a MTJ and a bit line over the top portion of the pillar.

In the embodiment of FIG. 5, the silicon substrate is etched to form the pillar, and the circumference of the pillar is isotropic-etched to form the surrounding gate. However, in the method of FIG. 6, the silicon is grown to form the pillar, and the gate electrode material is deposited over the circumference of the pillar, thereby obtaining the vertical transistor. In order to grow the pillar, a photoresist pattern where the pillar region is etched may be used instead of the metal film.

Any conventional methods for forming the vertical transistor can be used.

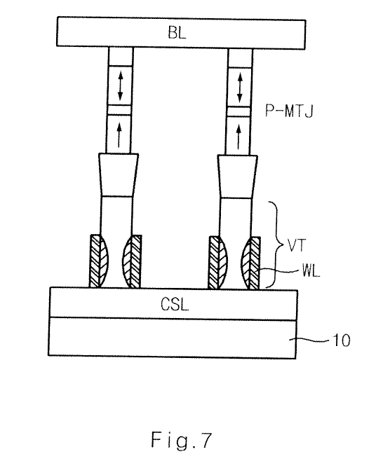

FIG. 7 is a diagram illustrating a spin transfer torque memory device according to another embodiment of the present invention.

In the spin transfer torque memory device of FIG. 7, a magnetization direction of a free ferromagnetic layer of an MTJ is different from that of a pinned ferromagnetic layer of the MTJ in comparison with the above embodiments. That is, while the magnetization directions of the free ferromagnetic layer and the pinned ferromagnetic layer are placed in parallel to the film surface in the above embodiments, magnetization directions of the free ferromagnetic layer and the pinned ferromagnetic layer are perpendicular to the film surface in the embodiment of FIG. 7, thereby forming a perpendicular MTJ (P-MTJ).

Since a magnetic material loses magnetism when the volume and size are decreased below a specific level, there is a limit in reduction of the size of the MTJ when the free ferromagnetic layer and the pinned ferromagnetic layer of the MTJ have a magnetization direction in parallel to the film surface. In order to improve the switching of the magnetization of the MTJ, the MTJ having a magnetization direction in parallel to the film surface is configured to have a width different from length. As a result, the size of the MTJ becomes larger.

Therefore, as shown in FIG. 7, the free ferromagnetic layer and the pinned ferromagnetic layer of the MTJ are formed with magnetic materials where the magnetization direction is perpendicular to the film surface, thereby maintaining characteristics of the MTJ so that the size of the MTJ can be smaller. Moreover, when a vertical transistor and a perpendicular magnetization MTJ are used in the embodiment of the invention, a device of less than 30 nm can be obtained.

The magnetic material where the magnetization direction is perpendicular to the film surface includes TbCoFe and FePt.

The above embodiments of the disclosure are illustrative and not limitative. Various alternatives and equivalents are possible. The invention is not limited by the type of deposition, etching polishing, and patterning steps describe herein. Nor is the invention limited to any specific type of semiconductor device. For example, the disclosure may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a spin transfer torque memory device, the method comprising:
forming a surrounding gate electrode on a circumference of a pillar;
implanting impurities into a silicon substrate to form a common source line; and
forming a MTJ over the pillar.

2. The method according to claim 1, further comprising forming a word line for connecting the surrounding gate electrode along a first direction.

3. The method according to claim 1, wherein the forming-a-gate-electrode includes:
etching the silicon substrate with a hard mask pattern to form a top portion of the pillar;
forming a spacer at sidewalls of the top portion of the pillar isotropically;
etching the silicon substrate with the spacer as a mask to form a bottom portion of the pillar;
etching the bottom portion of the pillar;
forming a gate electrode conductive film;
etching the gate electrode conductive film so that the etched bottom portion of the pillar is surrounded by the gate electrode conductive film.

4. A method for manufacturing a spin transfer torque memory device, the method comprising:
forming a metal film over a silicon substrate;
selectively etching the metal film to expose the silicon substrate of a pillar region;
growing the exposed silicon substrate to form a pillar; and
forming a MTJ over the pillar.

5. The method according to claim 4, further comprising:
forming a surrounding gate electrode in the circumference of the pillar; and
forming a word line for connecting the surrounding gate electrode along a first direction.

6. The method according to claim 5, wherein the forming-a-surrounding-gate-electrode includes:
forming a gate electrode material over the surface of the pillar and the surface of the metal film;
etching the gate electrode material formed over the surface of the metal film; and
removing the gate electrode material formed over the top surface of the pillar and the surface of the metal film.
